(19) United States
(12) Patent Application Publication
(10) Pub. No.: US 2021/0132455 A1
(43) Pub. Date: May 6, 2021

(54) ARRAY SUBSTRATE AND METHOD OF MANUFACTURING THE SAME, LIQUID CRYSTAL DISPLAY PANEL, DISPLAY DEVICE AND METHOD OF DRIVING THE SAME

(71) Applicants: Wuhan BOE Optoelectronics Technology Co.,Ltd., Wuhan, Hubei (CN); BOE TECHNOLOGY GROUP CO., LTD., Beijing (CN)

(72) Inventors: Peng CHEN, Beijing (CN); Jian ZHAO, Beijing (CN); Dalong MAO, Beijing (CN); Zizheng LIU, Beijing (CN); Zhixian WANG, Beijing (CN)

(21) Appl. No.: 16/847,025

(22) Filed: Apr. 13, 2020

(30) Foreign Application Priority Data
Oct. 31, 2019 (CN) 201911053760.8

(51) Int. Cl. G02F 1/1362; H01L 27/12; G02F 1/1368; G02F 1/1343; H01L 29/786; G02F 1/1345; G09G 3/36

(52) U.S. Cl. CPC G02F 1/136286; H01L 27/124; G02F 1/1368; G02F 1/13439; H01L 29/78696; G02F 1/13624; G09G 2310/0213; G02F 1/13452; H01L 27/1259; G09G 3/3696; G09G 3/3688; G02F 2001/13685; G02F 2001/136295; G02F 1/134309

(57) ABSTRACT

An array substrate includes a first base, and gate lines, data lines and common electrode lines disposed above the first base. The gate lines and the data lines extend in a first direction, and the common electrode lines extend in a direction intersected with the first direction. The gate lines, the data lines and the common electrode lines are insulated from one another. Orthographic projections of the gate lines and the data lines on the first base are not overlapped. The gate lines and/or the data lines define a plurality of sub-pixel regions together with the plurality of common electrode lines.

### CROSS-REFERENCE TO RELATED APPLICATION

The present application claims priority to and the benefit of Chinese Patent Application No. 201911053760.8 filed Oct. 31, 2019, which is incorporated herein by reference in its entirety.

### TECHNICAL FIELD

The present disclosure relates to the field of display technologies, and in particular to an array substrate and a method of manufacturing the same, a liquid crystal display panel, a display device and a method of driving the same.

### BACKGROUND

A thin film transistor liquid crystal display (TFT-LCD) occupies a dominant position in the current display field due to its advantages of light weight, small thickness, low power consumption, stable performance and relatively low cost. At present, the liquid crystal display continues to develop in a direction of large-size. As the size of the display panel increases, demand for the yield of the display panel is getting higher and higher.

### SUMMARY

In an aspect, an array substrate is provided, the array substrate includes: a first base; gate lines disposed above the first base and extending in a first direction, the gate lines being configured to provide scanning signals; data lines disposed above the first base and extending in the first direction, the data lines being configured to provide data voltage signals; and common electrode lines disposed above the first base and extending in a second direction intersected with the first direction, the common electrode lines being configured to provide common voltage signals. The gate lines, the data lines and the common electrode lines are insulated from one another, orthographic projections of the gate lines and the data lines on the first base do not overlap, and the gate lines and/or the data lines define the plurality of sub-pixel regions together with the common electrode lines.

In some embodiments, the array substrate further includes thin film transistors and pixel electrodes that are disposed above the first base, each sub-pixel region having at least one thin film transistor and a pixel electrode therein. Each thin film transistor includes a gate, an active pattern, a source and a drain. Sources of all thin film transistors in each column of sub-pixel regions arranged in the first direction are electrically connected to a corresponding data line, gates of all thin film transistors in the column of sub-pixel regions are electrically connected to a respective one of the gate line, and a drain of each thin film transistor in the column of sub-pixel regions is electrically connected to a corresponding pixel electrode.

In some embodiments, the pixel electrodes are disposed in a same layer and made of a same material as the common electrode lines.

In some embodiments, the gate lines and the data lines are arranged alternately in the second direction. The gate lines and the data lines are divided into a plurality of groups, each group includes a gate line and a data line most proximate to the gate line in the gate lines; and a gate line and a data line most proximate to each other in two adjacent groups define a sub-pixel region together with two adjacent common electrode lines.

In some embodiments, the gate lines are arranged at intervals in the second direction, and the gate lines are divided into a plurality of gate line groups, each gate line group includes two gate lines most proximate to each other in the gate lines. One of the data lines is disposed between the two gate lines in the gate line group; and in two adjacent gate line groups, a gate line in one gate line group most proximate to another gate line group, a gate line in the another gate line group most proximate to the one gate line group define two sub-pixel regions together with two adjacent common electrode lines.

In some embodiments, the gate is disposed between the active pattern and the first base as a bottom gate. The thin film transistor further includes a top gate disposed at a side of the source and the drain away from the first base, and the top gate is electrically connected to the bottom gate.

In some embodiments, a portion of a gate line connected to the thin film transistor serves as the top gate of the thin film transistor.

In some embodiments, an orthographic projection of the active pattern on the first base is within a range of an orthographic projection of the bottom gate on the first base. The orthographic projection of the active pattern on the first base is within a range of an orthographic projection of the portion of the gate line connected to the thin film transistor on the first base.

In some embodiments, each thin film transistor is configured in a way that a channel of the thin film transistor is U-shaped.

In some embodiments, the at least one thin film transistor includes two thin film transistors.

In some embodiments, the array substrate further includes common electrodes. At least one common electrode corresponds to each row of sub-pixel regions arranged in the second direction, and the at least one common electrode is electrically connected to a corresponding common electrode line.

In some embodiments, each common electrode is disposed in a respective one of the plurality of sub-pixel regions; or, at least two common electrodes correspond to each row of sub-pixel regions.

In another aspect, a liquid crystal display panel is provided, the liquid crystal display panel includes the array substrate.

In some embodiments, the liquid crystal display panel further includes an opposite substrate and a liquid crystal layer. The opposite substrate includes a second base and a plurality of post spacers disposed at a side of the second base proximate to the array substrate, an orthographic projection of each post spacer on the array substrate is within a region between a gate line and a data line most proximate to each other in the gate lines and the data lines. The liquid crystal layer is disposed between the array substrate and the opposite substrate.

In yet another aspect, a display device is provided. The display device includes the liquid crystal display panel, a gate driving circuit, a source driving circuit and a common electrode driving circuit. The gate driving circuit is connected to the gate lines, the gate driving circuit is configured to output scanning signals to the gate lines. The source driving circuit is connected to the data lines, the source driving circuit is configured to output data voltage signals to the gate lines. The common electrode driving circuit is connected to the common electrode lines, the common electrode driving circuit is configured to output common voltage signals to the common electrode lines.

In yet another aspect, a method of manufacturing the array substrate is provided. The method includes: forming the gate lines, the data lines and the common electrode lines above the first base. The gate lines and the data lines extend in the first direction and the common electrode lines extend in the second direction; the gate lines, the data lines and the common electrode lines are insulated from one another; orthographic projections of the gate lines and the data lines on the first base do not overlap; the gate lines and/or the data lines define the plurality of sub-pixel regions together with the common electrode lines.

In some embodiments, the method further includes: forming thin film transistors and pixel electrodes above the first base. Each sub-pixel region having at least one thin film transistor and a pixel electrode connected to the at least one thin film transistor therein, each thin film transistor includes a gate, an active pattern, a source and a drain: and all pixel electrodes and the common electrode lines are formed by a same patterning process; the source and the drain of the thin film transistor and the data lines are formed by a same patterning process.

In some embodiments, forming the at least one thin film transistor and the pixel electrode in each sub pixel region, includes: forming at least one gate on the first base by a first patterning process; forming a gate insulating layer on the first base on which the at least one gate have been formed; forming an active pattern corresponding to each gate on the gate insulating layer by a second patterning process; forming a source and a drain on the active pattern by a third patterning process; forming a first insulating layer on the source and the drain by a fourth patterning process, the first insulating layer including at least one first via hole at a position corresponding to the drain; forming the pixel electrode on the first insulating layer by a fifth patterning process, the pixel electrode being electrically connected to the drain by the at least one first via hole; forming a second insulating layer on the pixel electrode by a sixth patterning process, the at least one second via hole extending through the second insulating layer, the first insulating layer and the gate insulating layer being formed; and forming the gate lines on the second insulating layer by a seventh patterning process, each gate line corresponding to a respective one column of a plurality of columns of sub-pixel regions, a gate line corresponding to the sub-pixel region being electrically connected to the gate by the at least one second via hole, orthographic projections of the gate and the gate line on the first base being overlapped.

In yet another aspect, a method of driving the display device is provided, the method includes: in an image frame: outputting, by the gate driving circuit, scanning signals sequentially to the gate lines; outputting, by the source driving circuit, data signals to the data lines; and outputting, by the common electrode driving circuit, a common voltage to each of the common electrode lines.

### BRIEF DESCRIPTION OF THE DRAWINGS

In order to describe technical solutions in embodiments of the present disclosure more clearly, the accompanying drawings to be used in the description of embodiments of the present disclosure will be introduced briefly below. Obviously, the accompanying drawings to be described below are merely some embodiments of the present disclosure, and a person of ordinary skill in the art may obtain other drawings according to these drawings. In addition, the drawings to be described below may be regarded as schematic diagrams, and are not limitations on an actual size of a product, an actual process of a method and an actual timing of signals that the embodiments of the present disclosure relate to.

FIG. 1A is a framework structure diagram of display device, according to some embodiments of the present disclosure;

FIG. 1B is a structure diagram of liquid crystal display panel, according to some embodiments of the present disclosure;

FIG. 2A is a structure diagram of backlight module, according to some embodiments of the present disclosure;

FIG. 2B is a structure diagram of another backlight module according to some embodiments of the present disclosure;

FIG. 3A is a top view of a liquid crystal display panel, according to sortie embodiments of the present disclosure;

FIG. 3B is a top view of another liquid crystal display panel, according to some embodiments of the present disclosure;

FIG. 4 is a top view of an array substrate, according to some embodiments of the present disclosure;

FIG. 5 is a top view of another array substrate, according to some embodiments of the present disclosure;

FIG. 6A is a top view of a region indicated by R in FIG. 4, according to some embodiments of the present disclosure;

FIG. 6B is a section of the array substrate along A-A′ in FIG. 6A, according to some embodiments of the present disclosure;

FIG. 6C is a section of the array substrate along G-G′ in FIG. GA, according to some embodiments of the present disclosure;

FIG. 7 is a top view of yet another array substrate, according to some embodiments of the present disclosure;

FIG. 8 is a top view of yet another array substrate, according to some embodiments of the present disclosure;

FIG. 9A is a top view of a region indicated by Q in FIG. 8, according to some embodiments of the present disclosure;

FIG. 9B is a section of the array substrate along B-B′ in FIG. 9A, according to some embodiments of the present disclosure;

FIG. 9C is a section of the array substrate along C-C′ in FIG. 9A, according to some embodiments of the present disclosure;

FIG. 10A is a top view of yet another array substrate, according to some embodiments of the present disclosure;

FIG. 10B is a top view of yet another array substrate, according to some embodiments of the present disclosure;

FIG. 11 is a top view of a display device, according to some embodiments of the present disclosure;

FIG. 12 is a flow chart of forming thin film transistors and a pixel electrode connected to the thin film transistors, according to some embodiments of the present disclosure;

FIG. 13A is a top view showing a structure formed after gates and a gate insulating layer are formed, according to some embodiments of the present disclosure;

FIG. 13B is a section of the structure along D-D′ in FIG. 13A, according to some embodiments of the present disclosure;

FIG. 14 is a top view showing a structure formed after active patterns are formed, according to some embodiments of the present disclosure;

FIG. 15 is a top view showing a structure formed after sources and drains are formed, according to some embodiments of the present disclosure;

FIG. 16A is a top view showing a structure formed after a first insulating layer including first via holes is formed, according to some embodiments of the present disclosure;

FIG. 16B is a section of the structure along E-E′ in FIG. 16A, according to some embodiments of the present disclosure;

FIG. 17 is a top view showing a structure formed after a pixel electrode is formed, according to some embodiments of the present disclosure;

FIG. 18A is a top view showing a structure formed after a second insulating layer including second via holes is formed, according to some embodiments of the present disclosure;

FIG. 18B is a section of the structure along F-F′ in FIG. 18A, according to some embodiments of the present disclosure; and

FIG. 19 is a flow chart of a method of driving a display panel, according to some embodiments of the present disclosure.

### DETAILED DESCRIPTION

The technical solutions in some embodiments of the present disclosure will be described clearly and completely with reference to the accompanying drawings. Obviously, the embodiments to be described are merely some embodiments of the present disclosure rather than all embodiments. All other embodiments obtained by a person of ordinary skill in the art on the basis of the embodiments of the present disclosure are within the protection scope of the present disclosure.

It will be understood that in the description of the present disclosure, orientations or positional relationships indicated by terms “upper”, “lower”, “left”, “right”, “vertical”, “horizontal”, “top”, “bottom”, etc. are based on orientations or positional relationships shown in the drawings, merely to facilitate and simplify the description of the present disclosure, but not to indicate or imply that the referred devices or elements must have a particular orientation, or must be constructed or operated in a particular orientation. Therefore, they should not be construed as limitations to the present disclosure.

Unless the context requires otherwise, the term “comprise” and other forms thereof such as the third-person singular form “comprises” and the present participle form “comprising” in the description and the claims are construed as open and inclusive, i.e., “inclusive, but not limited to”. In the description of the specification, the terms such as “one embodiment”, “some embodiments”, “exemplary embodiments”, “example”, “specific example” or “some examples” are intended to indicate that specific features, structures, materials or characteristics related to embodiment(s) or example(s) are included in at least one embodiment or example of the present disclosure. Schematic representations of the above terms do not necessarily refer to same embodiment(s) or example(s). In addition, the specific features, structures, materials or characteristics may be included in any one or more embodiments or examples in any suitable manner.

Below, the terms “first” and “second” are only used for describing purpose, and cannot be construed as indicating or implying relative importance or implicitly indicating the number of technical features indicated. Therefore, features defined as “first” and “second” may explicitly or implicitly include one or a plurality of the features. In the description of embodiments of the present disclosure, “a plurality of” means two or more unless otherwise defined.

In the description of some embodiments, the terms such as “connected” and its extensions may be used. For example, the term “connected” may be used in description of some embodiments to indicate that two or more components are in direct physical or electrical contact with each other. However, the term “connected” may also mean that two or more components are not in direct contact with each other but still cooperate or interact with each other. The embodiments disclosed herein are not necessarily limited to the contents herein.

The expression “A and/or B” includes the following combinations: only A, only B, and A and B.

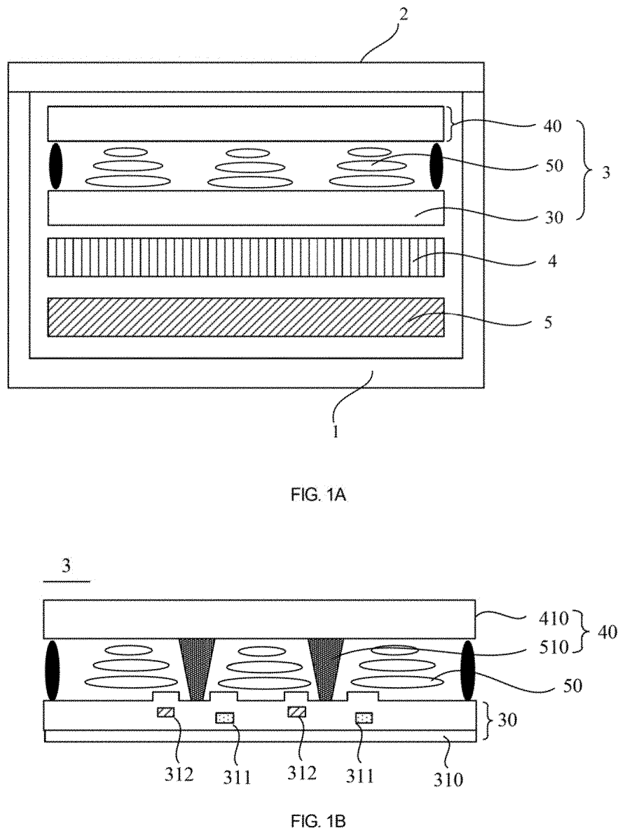

Some embodiments of the present disclosure provide a liquid crystal display device. As shown in FIG. 1A, the liquid crystal display device mainly includes a framework 1, a cover glass 2, a liquid crystal display panel 3, a backlight module 4, a circuit board 5 and other electronic components.

The circuit board 5 is configured to provide signals required for display to the liquid crystal display panel 3. For example, the circuit board 5 is a printed circuit board assembly (PCBA), and the PCBA includes a printed circuit board (PCB) and timing controller (TCON), power management integrated circuit (PMIC) other integrated circuit (IC) or circuits, etc.

For example, a longitudinal section of the framework 1 is U-shaped, and as shown in FIG. 1A, the liquid crystal display panel 3, the backlight module 4, the circuit board 5 and the other electronic components are disposed in the framework 1. The backlight module 4 is disposed below the liquid crystal display panel 3. The circuit board 5 is disposed below the backlight module 4. The cover glass 2 is disposed at a side of the liquid crystal display panel 3 away from the backlight module 4.

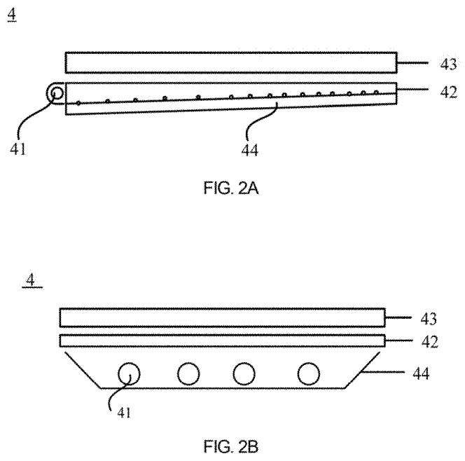

As shown in FIGS. 2A and 2B, the backlight module 4 includes a backlight 41, a light guide plate 42, at least one optical film 43 that is disposed on a light exit side of the light guide plate 42, etc. FIG. 2A illustrates a wedge-shaped light guide plate 42, and FIG. 28 illustrates a plate-shaped light guide plate 42. The at least one optical film 43 includes, for example, a diffusion sheet and/or at least one brightness enhancement film. The at least one brightness enhancement film includes, for example, a prism sheet and a dual brightness enhancement film.

The backlight 41 includes, for example, light-emitting diodes (LEDs). As shown in FIG. 2A, the backlight 41 may be disposed at a left side of the light guide plate 42. In this case, the backlight module 4 is an edge-lit backlight module. As shown in FIG. 2B, the backlight 41 may be disposed below the light guide plate 42. In this case, the backlight module 4 is a backlit backlight module. The structures of the backlight module 4 in FIGS. 2A and 2B are merely exemplary, and are not limited herein. In addition, as shown in FIGS. 2A and 2B, the backlight module 4 may further include a reflective sheet 44. For an edge-lit backlight module, the reflective sheet 44 is disposed on a surface of the light guide plate 42 facing away from the light exit side. For a backlit backlight module, the reflective sheet 44 is disposed at a side of the backlight 41 away from the light guide plate 42.

As shown in FIGS. 1A and 1B, in some embodiments, the liquid crystal display panel 3 includes an array substrate 30, an opposite substrate 40, and a liquid crystal layer 50 disposed between the array substrate 30 and the opposite substrate 40. For example, the array substrate 30 and the opposite substrate 40 may be bonded together through a frame sealant, so that liquid crystal molecules in the liquid crystal layer 50 are accommodated in a space enclosed by the frame sealant.

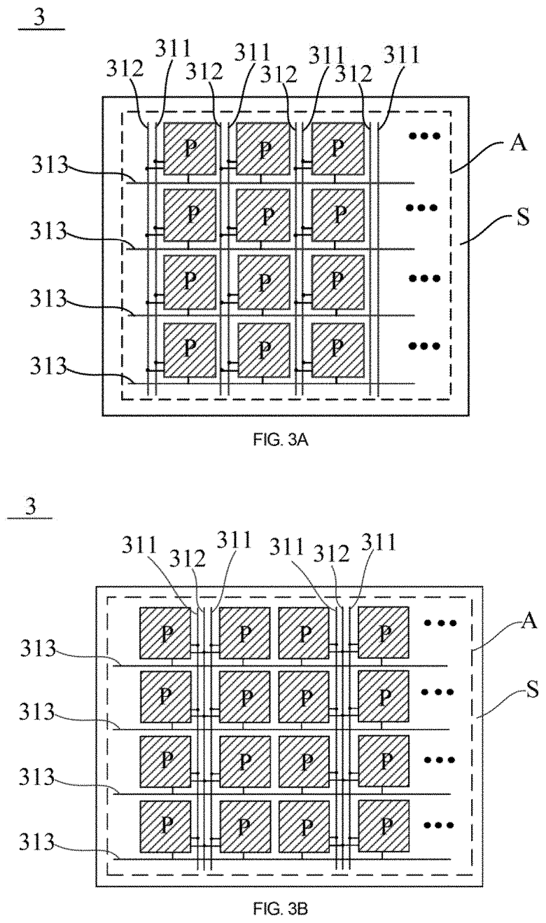

As shown in FIGS. 3A and 3B, the liquid crystal display panel 3 has a display area A and a peripheral area S. For example, the peripheral region S is disposed around the display region A. A plurality of sub-pixels P are disposed in the display region A, and the plurality of sub-pixels P at least include sub-pixels of a first color, sub-pixels of a second color and sub-pixels of a third color. The first color, the second color and the third color are three primary colors (for example, red, green and blue, respectively).

FIGS. 3A and 3B illustrate a plurality of sub-pixels P arranged in an array, but the arrangement manner of the sub-pixels P is not limited thereto.

In related art, in the array substrate, gate lines and data lines are generally arranged crosswise to define sub-pixel regions. However, in this arrangement manner, the gate lines and the data lines have overlapped regions therebetween, and a large parasitic capacitance usually exists between a gate line and a data line in their overlapped region, thereby increasing a probability of poor display such as flicker in the display device and affecting the display effect of the display device.

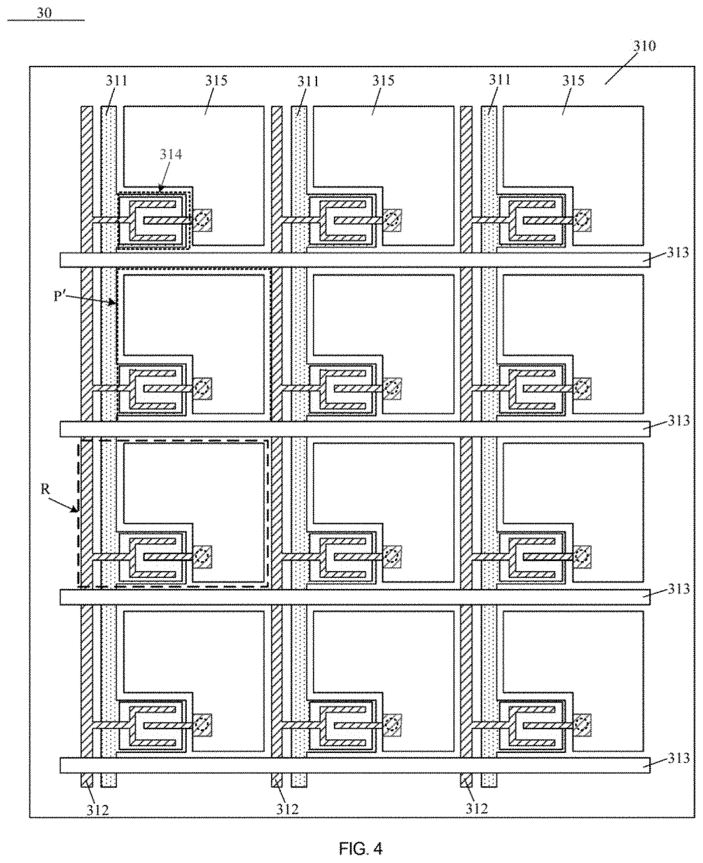

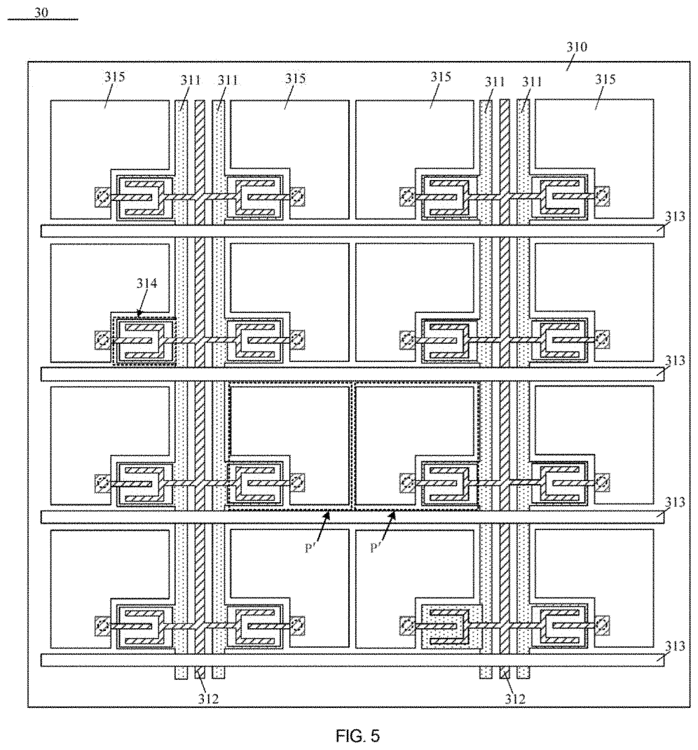

However, in some embodiments of the present disclosure, as shown in FIGS. 4 and 5, the array substrate 30 includes a first base 310, and gate lines 311, data lines 312 and common electrode lines 313 that are all disposed above the first base 310. The gate lines 311 are configured to provide scanning signals, the data lines 312 are configured to provide data voltage signals, and the common electrode lines 313 are configured to provide common voltage signals. The gate lines 311 and the data lines 312 extend in a first direction, and the common electrode lines 313 extend in a second direction intersected with the first direction. The first direction is, for example, perpendicular to the second direction. For another example, an angle between the first direction and the second direction is an acute angle. In a thickness direction of the first base 310, orthographic projections of the gate lines 311 and the data lines 312 on the first base 310 do not overlap.

The gate lines 311, the data lines 312 and the common electrode lines 313 are insulated from one another. In this case, the gate lines 311 are insulated from each other, the data lines 312 are insulated from each other, and the common electrode lines 313 are insulated from each other.

The gate lines 311 and/or the data lines 312 define a plurality of sub-pixel regions P′ together with the common electrode lines 313. A region where each sub-pixel P is located is a sub-pixel region P′. For example, the gate lines 311 and the common electrode lines 313 define a plurality of sub-pixel regions P. For another example, the data lines 312 and the common electrode lines 313 define a plurality of sub-pixel regions P′. For another example, the gate lines 311 and the data lines 312 define a plurality of sub-pixel regions P′ together with the common electrode lines 313.

In the embodiments of the present disclosure, since the gate lines 311 are parallel to the data lines 312, and the orthographic projections of the gate lines 311 and the data lines 312 on the first base 310 do not overlap, there is no overlapped region between the gate lines 311 and the data lines 312, thereby avoiding high parasitic capacitance existing between the gate lines 311 and the data lines 312.

In some examples, the width of the common electrode line 313 is less than that of the gate line 311. In this way, the overlapped region of the common electrode line 313 and the gate line 311 has a small area, resulting in a low parasitic capacitance. Thus, a probability of poor display such as flicker of the display device may be reduced, and the display effect may be improved.

In some examples, as shown in FIG. 4, the gate lines 311 and the data lines 312 are arranged alternately in the second direction. The gate lines 311 and the data lines 312 are divided into a plurality of groups, each group includes a gate line 311 and a data line 312 most proximate to the gate line 311 in the gate lines 311. A gate line 311 and a data line 312 most proximate to each other in two adjacent groups define a sub-pixel region P′ together with two adjacent common electrode lines 313. The number of gate lines 311, the number of data lines 312 and the number of the plurality of columns of sub-pixel regions P′ are the same. The second direction herein is, for example, the row direction, and the first direction is the column direction.

In some other examples, as shown in FIG. 5, the gate lines 311 are arranged at intervals in the second direction. The gate lines 311 are divided into a plurality of gate line groups, and each gate line group includes two gate lines 311 most proximate to each other in the gate lines 311. One of the data lines 312 is disposed between the two gate lines 311 in each gate line group. In two adjacent gate line groups, a gate line in one gate line group most proximate to another gate line group, a gate in the another gate line group most proximate to the one gate line group define two sub pixel-regions P′ together with two adjacent common electrode lines 313. The number of gate lines 311 is the same as the number of the columns of sub-pixel regions P′, and the number of data lines 312 is less than the number of gate lines 311.

In some embodiments, as shown in FIGS. 4, 5 and 8, the array substrate 30 further includes pixel electrodes 315. A pixel electrode 315 is disposed in one of the plurality of sub-pixel regions P′. For example, a pixel electrode 315 is disposed in each sub-pixel region P′. In some examples, the pixel electrodes 315 are disposed in a same layer and made of a same material as the common electrode lines 313.

The description “in a same layer” means that in a process of forming the pixel electrodes 315 and the common electrode lines 313, a layer is formed by a same film forming process such as coating, inkjet printing, etc., and then a layer structure with specific patterns is formed by using a same mask and by performing a single patterning process. According to different specific patterns, the single patterning process may include multiple exposure, developing or etching processes. The specific patterns in the layer structure may be continuous or discontinuous and the specific patterns may be at different heights or may have different thicknesses.

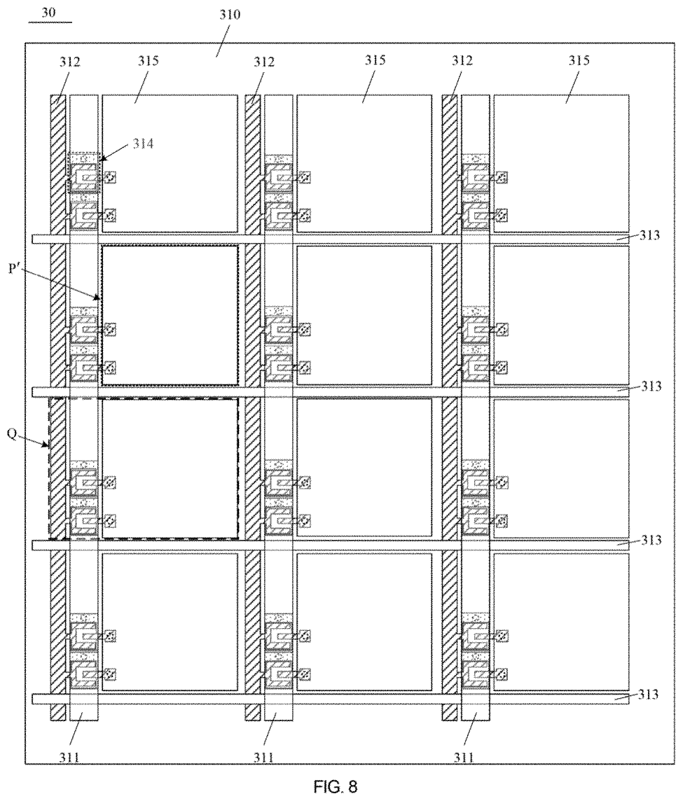

In some embodiments, as shown in FIGS. 4, 5 and 8, the array substrate 30 further includes thin film transistors 314. At least one thin film transistor 314 is disposed in one of the plurality of sub-pixel regions P′. In some examples, at least one thin film transistor 314 is disposed in each sub-pixel region P′. For example, as shown in FIGS. 4 and 5, there is one thin film transistor 314 in a sub-pixel region P′. For another example, as shown in FIG. 8, there are two thin film transistors 314 in a sub-pixel region P′.

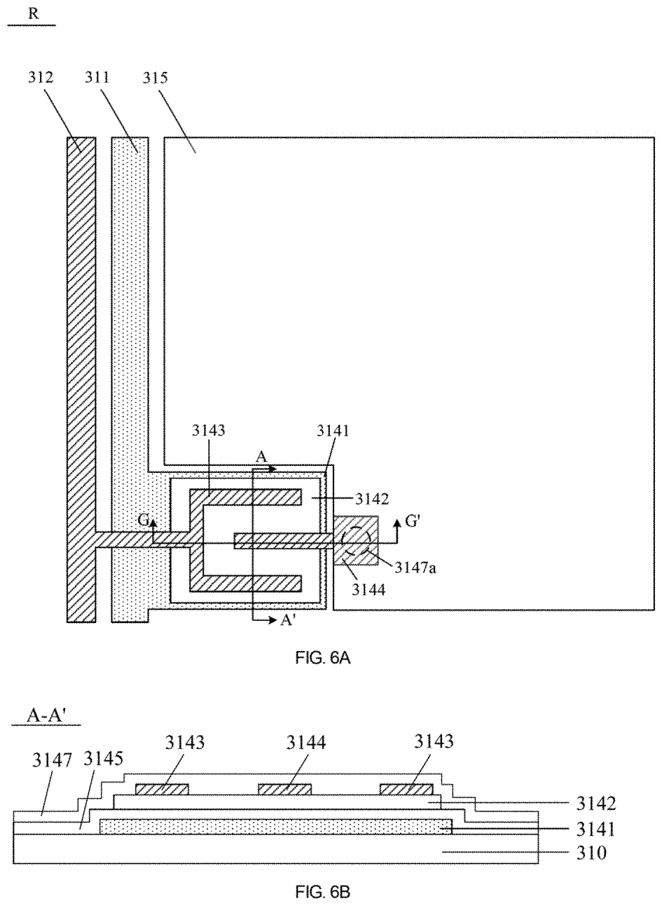

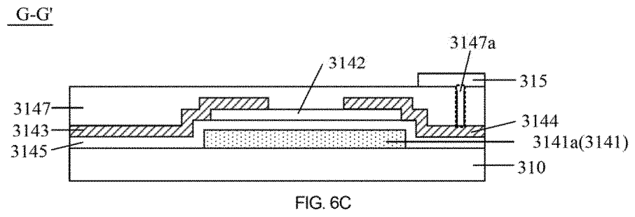

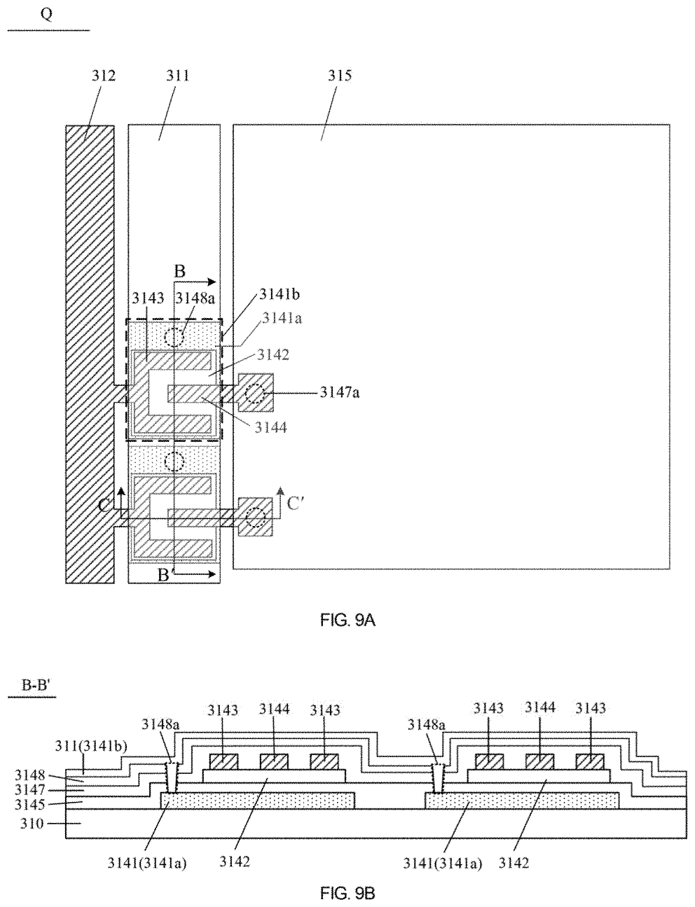

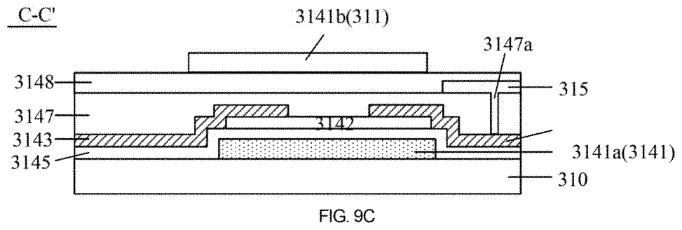

As shown in FIGS. 6A, 6B and 6C, the thin film transistor 314 includes a gate 3141, an active pattern 3142, a source 3143 and a drain 3144. In a case where there is one thin film transistor 314 in a sub-pixel region P′, as shown in FIGS. 4 and 5, the gate 3141 is electrically connected to a gate line 311, the source 3143 is electrically connected to a data line 312, and the drain 3144 is electrically connected to a pixel electrode 315 disposed in the sub-pixel region P′. In a case where there are two thin film transistors 314 in a sub-pixel region P′ as shown in FIGS. 8 and 9A, the gates 3141 of the thin film transistors 314 are electrically connected to a same gate line 311, the sources 3143 of the thin film transistors 314 are electrically connected to a same data line 312, and the drains 3144 of the thin film transistors 314 are electrically connected to a pixel electrode 315 disposed in the sub-pixel region P′. That is, a same pixel electrode 315 is driven by the two thin film transistors 314. In a case where one of the thin film transistors 314 is in failure, the pixel electrode 315 may be driven by the other thin film transistor 314 to operate normally, thereby increasing the yield of the liquid crystal display panel 3 including the array substrate 30.

As shown in FIGS. 4, 5 and 8, for each column of sub-pixel regions P′ arranged in the first direction, sources 3143 of all thin film transistors 314 in the column of sub-pixel regions P′ are electrically connected to a corresponding data line 312, gates 3141 of all thin film transistors 314 in the column of sub-pixel regions P′ are electrically connected to a respective one of the gate lines 311, and a drain 3144 of each thin film transistor 314 in the column of sub-pixel regions P′ is electrically connected to a corresponding pixel electrode 315.

For example, as shown in FIG. 4, the gate line 311 and the data line 312 in each group are connected to the thin film transistors 314 in a corresponding column of sub-pixel regions P′. For another example, as shown in FIG. 5, the two gate lines 311 in each gate line group are connected to the thin film transistors 314 in two columns of sub pixel-regions P′ at two sides of the gate line group, and the data line 312 located between the two gate lines 311 in each gate line group is connected to the thin film transistors 314 in the two columns of sub-pixel regions P′.

FIGS. 6A, 6B and 6C illustrate a bottom-gate thin film transistor as the thin film transistor 314, but the embodiments of the present disclosure are not limited thereto.

For example, as shown in FIGS. 6B to 6C, 8 and 9A to 9C, the gate 3141 of the thin film transistor 314 is disposed between the active pattern 3142 and the first base 310 as a bottom gate 3141a.

For example, as shown in FIGS. 9A to 9C, the thin film transistor 314 further includes a top gate 3141b disposed at a side of the source 3143 and the drain 3144 away from the first base 310, and the top gate 3141b is electrically connected to the bottom gate 3141a.

As shown in FIGS. 9A to 9C, the array substrate 30 further includes a gate insulating layer 3145 disposed between the gate 3141 and the active pattern 3142. For example, as shown in FIGS. 9A to 9C, the array substrate 30 may further include a first insulating layer 3147 disposed between both the source 3143 and the drain 3144 and the pixel electrode 315, and a second insulating layer 3148 disposed between the top gate 3141b and the pixel electrode 315. At least one second via hole 3148a extending through the gate insulating layer 3145, the first insulating layer 3147 and the second insulating layer 3148 is provided, and the top gate 3141b is electrically connected to the bottom gate 3141a through the at least one second via hole 3148a.

By setting the thin film transistor 314 as a double-gate thin film transistor, the time taken to turn on or off the thin film transistor 314 may be reduced, and the response speed of the thin film transistor 314 may be improved.

In some examples, as shown in FIGS. 8 and 9A to 9C, a portion of a gate line 311 connected to the thin film transistor 314 serves as the top gate 3141b of the thin film transistor 314. In this way, the gate line 311 does not need to be formed separately and the process is simplified.

On this basis, in some examples, as shown in FIGS. 9A to 9C, in the thickness direction of the first base 310, an orthographic projection of the active pattern 3142 on the first base 310 is within a range of an orthographic projection of the bottom gate 3141a on the first base 310.

In some examples, the orthographic projection of the active pattern 3142 on the first base 310 is within a range of an orthographic projection of the portion of the gate line 311 connected to the thin film transistor 314 on the first base 310.

In this way, the bottom gate 3141a may block light incident onto the active pattern 3142 from the backlight module 4, and the gate line 311 may block light incident onto the active pattern 3142 from the outside, thereby reducing the effect of light on the leakage current in the channel of the thin film transistor 314, and improving the stability of the thin film transistor 314. Meanwhile, the gate line 311 may replace a black matrix in the opposite substrate 40, and function to block the light-leaking. Therefore, there is no need to additionally provide a mask for forming the black matrix in the whole manufacturing process of the liquid crystal display panel 3, thereby reducing the cost.

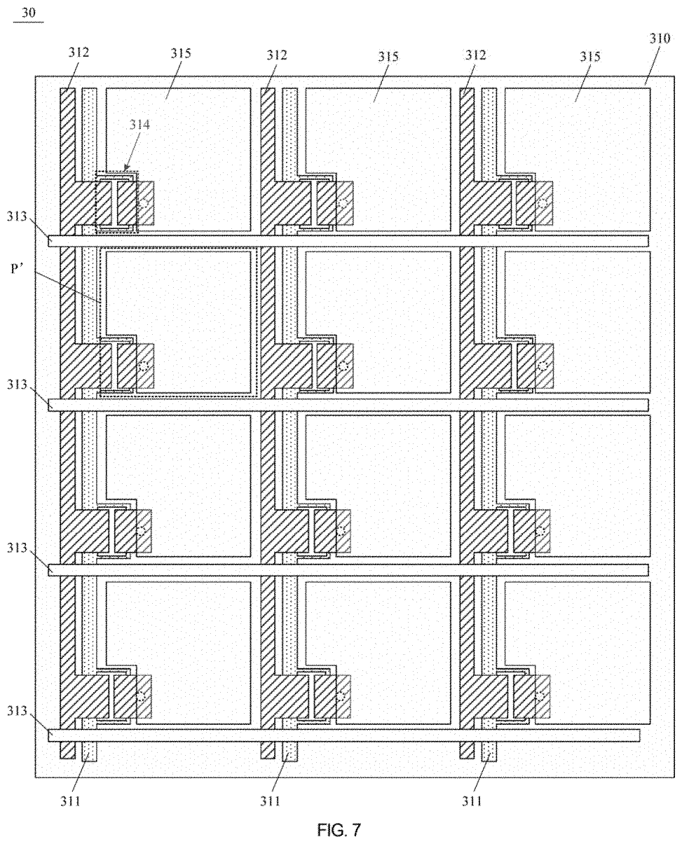

In some examples, as shown in FIGS. 4, 5, 6A and 9A, a channel of each thin film transistor 314 is U-shaped. Of course, the channel of the thin film transistor 314 may be I-shaped. That is, as shown in FIG. 7, the source 3143 and the drain 3144 are located on two opposite sides of the gate 3141, respectively.

The thin film transistor 314 having a U-shaped channel has a high width-to-length ratio, and the thin film transistor 314 having such a structure may be applied in a gate driving circuit.

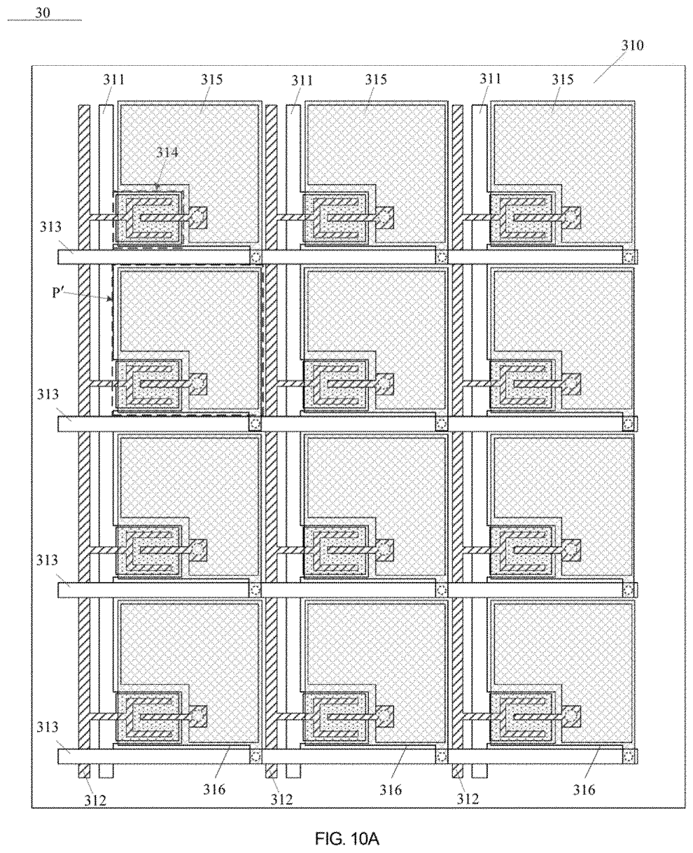

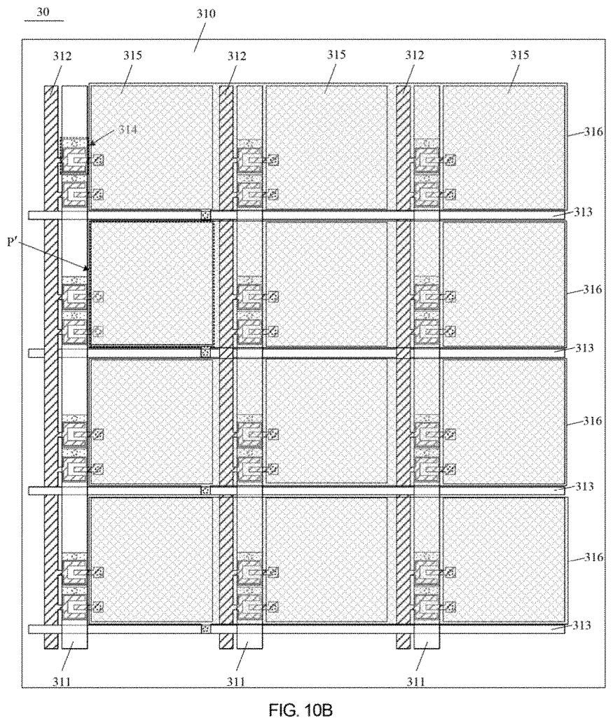

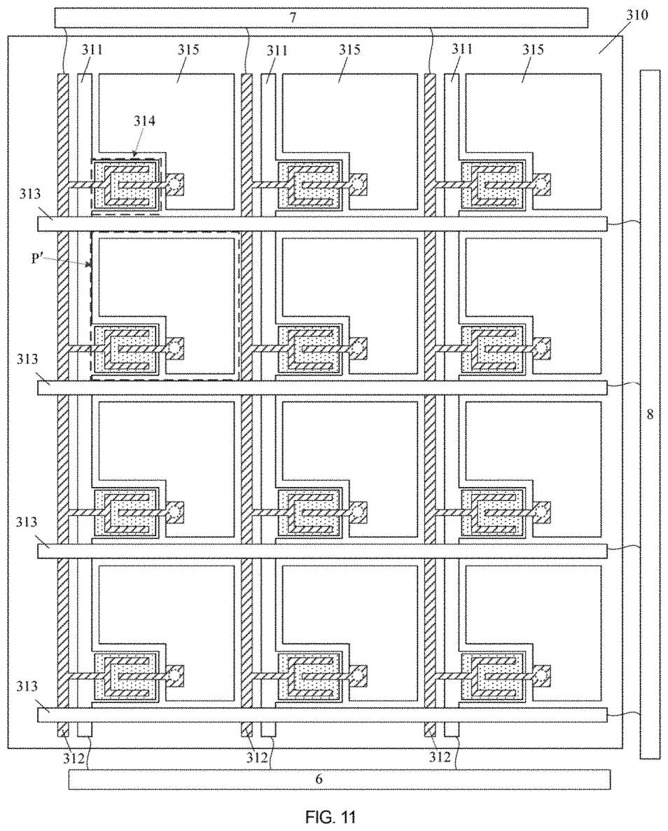

As shown in FIGS. 10A and 10B, in some embodiments, the array substrate 30 further includes common electrodes 316. Each row of sub-pixel regions P′ arranged in the second direction corresponds to at least one common electrode 316, and the at least one common electrode 316 is electrically connected to a corresponding common electrode line 313, which is configured to provide common voltages to the at least one common electrodes 316.

For example, as shown in FIG. 10A, each common electrode 316 is disposed in a respective one of the plurality of sub-pixel regions P′. For another example, as shown in FIG. 10B, at least two common electrodes 316 corresponds to each row of sub-pixel regions P′.

In some embodiments, the common electrode 316 is disposed at a side of the pixel electrode 315 away from the first base 310.

It may be known from the above description that the common electrodes 316 are disposed at intervals and the common electrodes 316 in different rows of sub-pixels P are insulated from each other. It will be noted that the common electrodes 316 may also be disposed in the opposite substrate 40 rather than the array substrate 30.

In an example where the first direction is a vertical direction and the second direction is a horizontal direction, the working principle of the liquid crystal display panel 3 including the array substrate 30 will be described below.

In an image frame, the gate lines 311 sequentially output scanning signals. When any gate line 311 outputs a scanning signal, thin film transistors 314 in a column of sub-pixels P connected to the gate line 311 are turned on. After the thin film transistors 314 in the column of sub-pixels P are turned on, a data line 312 connected to the thin film transistors 314 in the column of sub-pixels P outputs a data voltage, so as to provide the data voltage to the pixel electrodes 315 in the column of sub-pixels P. Meanwhile, each common electrode line 313 outputs a common voltage to at least one common electrode 316 connected to the common electrode line 313. For each sub-pixel P, the deflection angle of liquid crystal molecules in the region where the sub-pixel P is located is controlled by the voltages of the pixel electrode 315 and the corresponding common electrode 316, so that the sub-pixel P may display different grayscales.

That is, for a same column of sub-pixels P, the voltage of all pixel electrodes 315 in the column of sub-pixels P is the same. In addition, in the column of sub-pixels P, the voltage of each common electrode 316 is input independently. The voltages of the common electrodes 316 corresponding to the column of sub-pixels P may be the same, may be not exactly the same, or may be different completely.

In the array substrate 30 provided in some embodiments of the present disclosure, in the second direction, at least one common electrode 316 corresponding to each row of sub-pixel regions P′ is electrically connected to a corresponding common electrode line 313, which may ensure the normal operation of the liquid crystal display panel 3 including the array substrate 30.

In addition, the gate lines 311 are parallel to the data lines 312, regions where the gate lines 311 and the data lines 312 are located have a thickness greater than that of regions between the gate lines 311 and the data lines 312 in the array substrate 30.

In some embodiments, as shown in FIG. 1B, the opposite substrate 40 includes a second base 410 and a plurality of post spacers (PSs) 510 disposed at a side of the second base 410 proximate to the array substrate 30. An orthographic projection of each post spacer 510 on the array substrate 30 is within a region between a gate line 311 and a data line 312 most proximate to each other in the gate lines 311 and the data lines 312.

In this way, an end of each post spacer 510 away from the second base 410 may be stuck in the region between the gate line 311 and data line 312 most proximate to each other on the array substrate 30. Therefore, the post spacer 510 may be prevented from sliding toward the sub-pixel region P′ when the liquid crystal display panel 3 is stressed excessively in its thickness direction. Since there is no need to provide any post spacer in the regions where the gate lines 311 are located, the width of each gate line may be made smaller, thereby increasing the aperture ratio of pixels.

As shown in FIG. 11, the display device provided in some embodiments of the present disclosure further includes a gate driving circuit 6, a source driving circuit 7 and a common electrode driving circuit 8.

The gate driving circuit 6 is connected to the gate lines 311. The gate driving circuit 6 may be directly disposed in the array substrate 30 by using technology of a gate driver on array (GOA), or the gate driving circuit 6 may be an integrated circuit (IC) bonded on the array substrate 30 or on a flexible printed circuit connected to the array substrate 30.

The source driving circuit 7 is connected to the data lines 312. The source driving circuit 7 may be an IC bonded on the array substrate 30 or on the flexible printed circuit connected to the array substrate 30.

The common electrode driving circuit 8 is connected to the common electrode lines 313. The common electrode driving circuit 8 is configured to output common voltages to the common electrode lines 313. The common electrode driving circuit 8 may be an IC bonded on the flexible printed circuit connected to the array substrate 30.

Some embodiments of the present disclosure provide a method of manufacturing the array substrate 30, the method includes the following steps.

As shown in FIGS. 4 and 5, gate lines 311, data lines 312 and common electrode lines 313 are formed above a first base 310. The gate lines 311 and the data lines 312 extend in the first direction, and the common electrode lines 313 extend in the second direction intersected with the first direction. For example, the first direction is perpendicular to the second direction. The gate lines 311, the data lines 312 and the common electrode lines 313 are insulated from one another. In a thickness direction of the first base 310, orthographic projections of the gate lines 311 and the data lines 312 on the first base 310 do not overlap. The gate lines 311 and/or the data lines 312 define a plurality of sub-pixel regions P′ together with the common electrode lines 313.

In this case, the thin film transistors 314 in a same column of sub-pixel regions P′ arranged in the first direction are connected to a same gate line 311 and a same data line 312, and at least one common electrode 316 corresponding to a same row of sub-pixel regions P′ arranged in the second direction is connected to a same common electrode line 313.

On this basis, the method of manufacturing the array substrate 30 further includes: as shown in FIGS. 4, 5 and 6A to 6B, forming at least one thin film transistor 314 and a pixel electrode 315 in each sub pixel region P′. The at least one thin film transistor 314 is connected to the pixel electrode 315. Each thin film transistor 314 includes a gate 3141, an active pattern 3142, a source 3143 and a drain 3144.

For each column of sub-pixel region P′ arranged in the first direction, sources 3143 of all thin film transistors 314 in the column of sub-pixel regions P′ are electrically connected to a corresponding data line 312, gates 3141 of all thin film transistors 314 in the column of sub-pixel regions P′ are electrically connected to a respective one of gate lines 311, and a drain 3144 of each thin film transistor 314 in the column of sub-pixel regions P′ is electrically connected to a corresponding pixel electrode 315.

In some examples, all the pixel electrodes 315 and the common electrode lines 313 are formed by a same patterning process. The source 3143 and the drain 3144 of the thin film transistor 314 and the data lines 312 are formed by a same patterning process. Each of the two patterning process includes depositing, coating photoresist, exposing by a mask, developing and etching. In this way, the manufacturing process of the array substrate 30 may be simplified.

For the advantages of the method of manufacturing the array substrate 30 provided in some embodiments of the present disclosure, reference may be made to the advantages of the array substrate 30 described above.

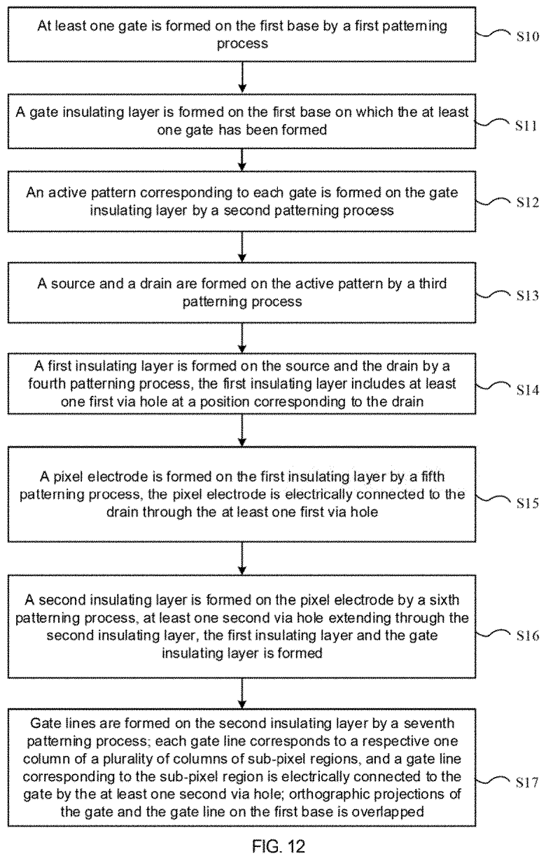

In some embodiments, as shown in FIG. 12, forming at least one thin film transistor 314 and a pixel electrode 315 in each sub pixel region P′ includes S10 to S17.

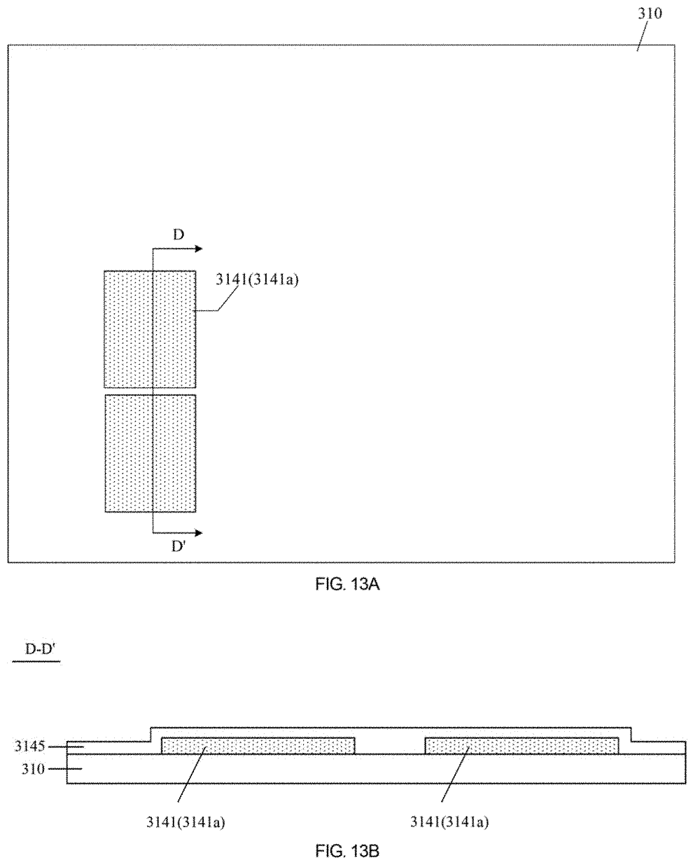

In S10, as shown in FIGS. 13A and 13B, at least one gate 3141 is formed on the first base 310 by a first patterning process.

In S11, as shown in FIGS. 13A and 13B, a gate insulating layer 3145 is formed on the first base 310 on which the at least one gate 3141 has been formed.

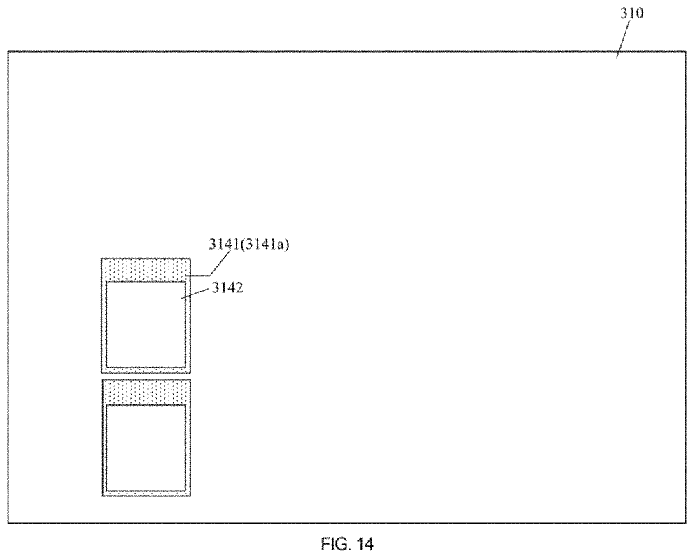

In S12, as shown in FIG. 14, an active pattern 3142 corresponding to each gate 3141 is formed on the gate insulating layer 3145 by a second patterning process.

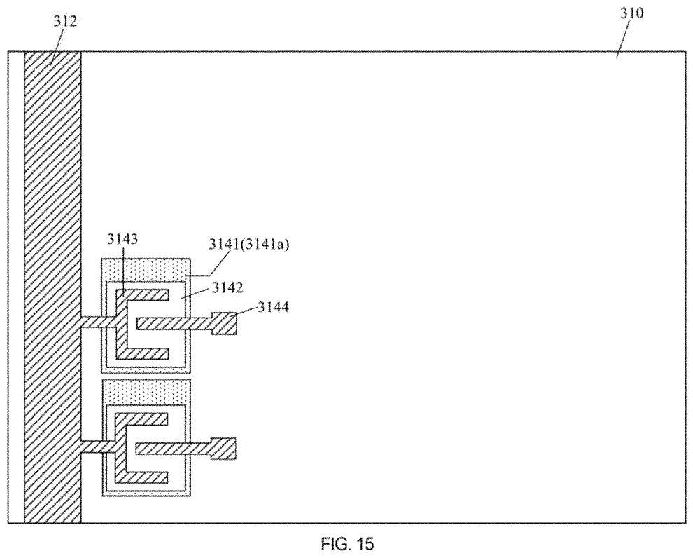

In S13, as shown in FIG. 15, a source 3143 and a drain 3144 are formed on the active pattern 3142 by a third patterning process.

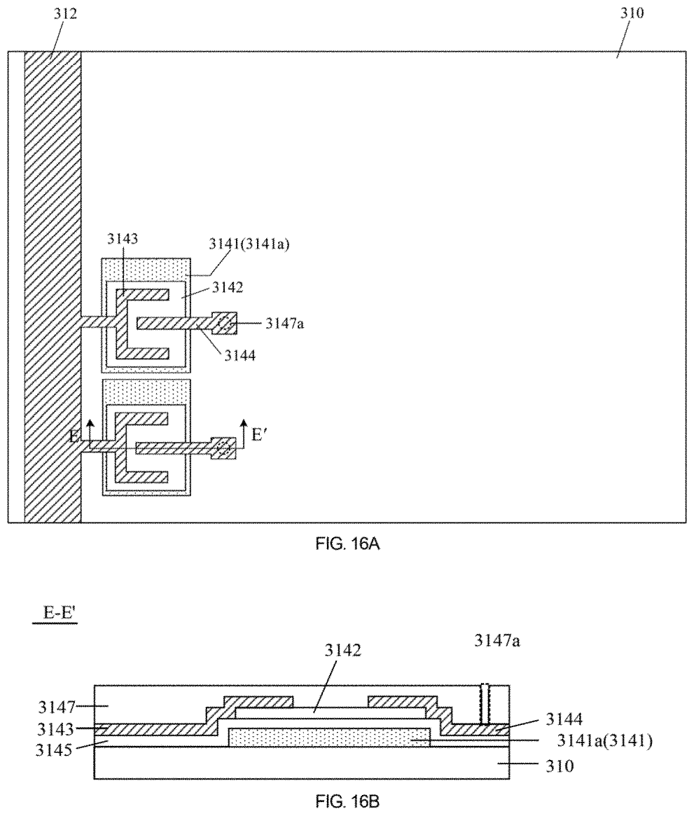

In S14, as shown in FIGS. 16A and 16B, a first insulating layer 3147 is formed on the source 3143 and the drain 3144 by a fourth patterning process. The first insulating layer 3147 includes at least one first via hole 3147a at a position corresponding to the drain 3144.

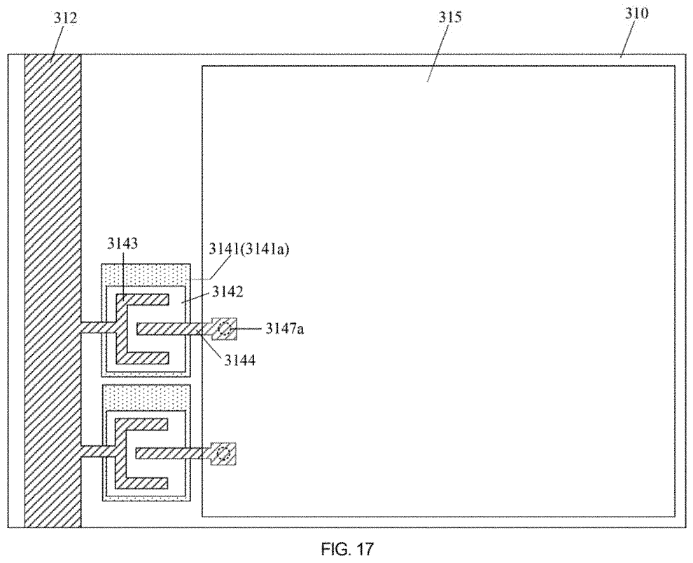

In S15, as shown in FIG. 17, a pixel electrode 315 is formed on the first insulating layer 3147 by a fifth patterning process. The pixel electrode 315 is electrically connected to the drain 3144 through the at least one first via hole 3147a.

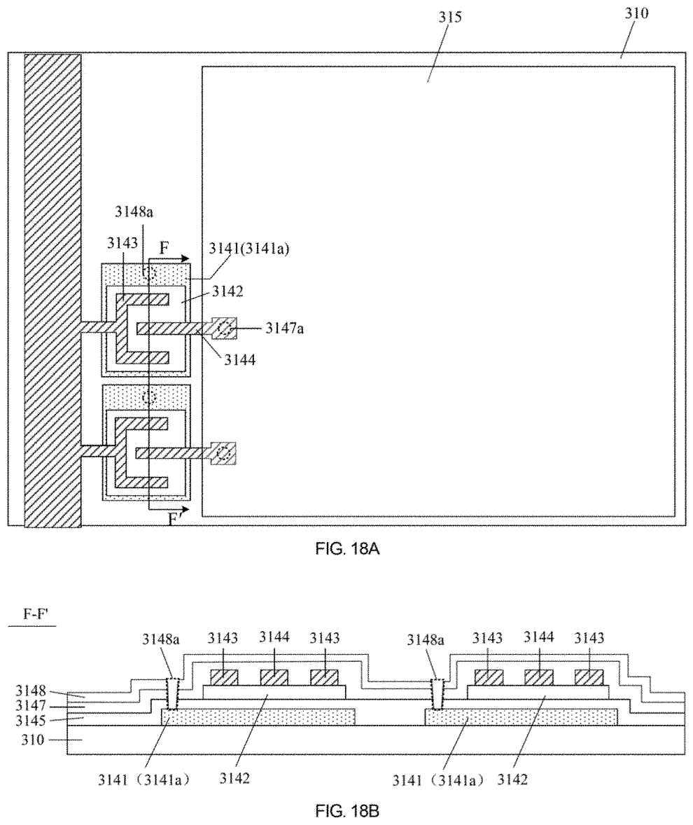

In S16, as shown in FIGS. 18A and 18B, a second insulating layer 3148 is formed on the pixel electrode 315 by a sixth patterning process. At least one second via hole 3148a extending through the second insulating layer 3148, the first insulating layer 3147 and the gate insulating layer 3145 is formed.

In S17 as shown in FIGS. 9A to 9C, gate lines 311 are formed on the second insulating layer 3148 by a seventh patterning process. Each gate line 311 corresponds to a respective one column of a plurality of columns of sub-pixel regions P′, and a gate line 311 corresponding to the sub-pixel region P′ is electrically connected to the gate 3141 by the at least one second via hole 3148a. Orthographic projections of the gate 3141 and the gate line 311 on the first base 310 is overlapped.

Each of the first patterning process to the seventh patterning process may include depositing, coating photoresist, exposing by a mask, developing and etching. Of course, in a case where a material of the first insulating layer 3147 is a photosensitive resin (for example, photoresist), the fourth patterning process merely includes coating photoresist, exposing by a mask, and developing. In a case where a material of the second insulating layer 3148 is a photosensitive resin (for example, photoresist), the sixth patterning process merely includes coating photoresist, exposing by a mask, and developing.

As shown in FIGS. 8 and 9A to 9C, the gate 3141 serves as a bottom gate 3141a of the thin film transistor 314, and a portion of the gate line 311a serves as the top gate 3141b of the thin film transistor 314 connected to the gate line 311.

By setting the thin film transistor 314 as a double-gate thin film transistor, the time taken to turn on or off the thin film transistor 314 may be reduced, and the response speed of the thin film transistor 314 may be improved. Since the portion of the gate line 311 also serves as the top gate 3141b of the at least one thin film transistor 314 connected to the gate line 311, the top gate 3141b does not need to be formed separately, and the manufacturing process is simplified. Meanwhile, the gate line 311 may block light incident onto the active pattern 3142 from the outside, thus, the effect of light on the leakage current in the channel of the thin film transistor 314 may be reduced, and the stability of the thin film transistor 314 may be improved. In addition, the gate line 311 may replace a black matrix in the opposite substrate 40, and function to block the light-leaking. Therefore, there is no need to additionally provide a mask for forming the black matrix in the whole manufacturing process of the liquid crystal display panel 3, thereby reducing the cost.

Optionally, in the thin film transistor 314, in the thickness direction of the first base 310, an orthographic projection of the active pattern 3142 on the first base 310 is within a range of an orthographic projection of the bottom gate 3141a on the first base 310.

The orthographic projection of the active pattern 3142 on the first base 310 is within the range of an orthographic projection of the portion of the gate line 311 connected to the thin film transistor 314 on the first base 310.

On this basis, the bottom gate 3141a may block light incident onto the active pattern 3142 from the backlight module 4, and the gate line 311 may block light incident onto the active pattern 3142 from the outside, thereby reducing the effect of light incident onto the array substrate 30 on the leakage current in the channel of the thin film transistor 314, and improving the stability of the thin film transistor 314.

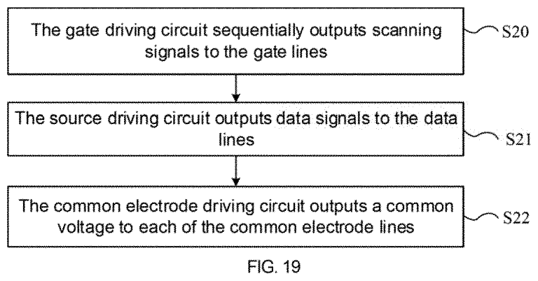

Some embodiments of the present disclosure provide a method of driving the display device. The method is used for driving the display device provided in the embodiments of the present disclosure. As shown in FIG. 19, the method includes S20 to S22 in an image frame.

In S20, the gate driving circuit sequentially outputs scanning signals to the gate lines 311.

In S21, the source driving circuit 7 outputs data signals to the data lines 312.

In S22, the common electrode driving circuit 8 outputs a common voltage to each of the common electrode lines 313.

The common electrode driving circuit 8 is controlled by an independent IC chip. The common electrode lines 313 are insulated from each other, and thus the common voltages on the common electrode lines 313 may be different.

In an example where the first direction is the vertical direction and the second direction is the horizontal direction, the working principle of the liquid crystal display panel 3 in the display device provided in the embodiments of the present disclosure will be described below.

In an image frame, when the gate driving circuit 6 outputs a scanning signal to any gate line 311, the thin film transistors 314 in a column of sub-pixels P connected to the gate line 311 are turned on. After the thin film transistors 314 in the column of sub-pixels P are turned on, the source driving circuit 7 outputs a data signal to a data line 312 connected to the sources 3143 of the thin film transistors 314 in the column of sub-pixels P, so as to provide a data voltage corresponding to the data signal to the pixel electrodes 315 in the column of sub pixels P. Meanwhile, the common electrode driving circuit 8 outputs a common voltage to each of the common electrode lines 313. For each sub-pixel P, the deflection angle of liquid crystal molecules in the region where the sub-pixel P is located is controlled by the voltages of the pixel electrode 315 and the corresponding common electrode 316, so that the sub-pixel P may display different grayscales.

The foregoing descriptions are merely specific implementation methods of the present disclosure, but the protection scope of the present disclosure is not limited thereto. Any person skilled in the art could readily conceive of changes or replacements within the technical scope of the present disclosure, which shall all be included in the protection scope of the present disclosure. Therefore, the protection scope of the present disclosure shall be subject to the protection scope of the claims.

What is claimed is:

1. An array substrate, comprising:
a first base;
gate lines disposed above the first base and extending in a first direction, the gate lines being configured to provide scanning signals;
data lines disposed above the first base and extending in the first direction, the data lines being configured to provide data voltage signals; and
common electrode lines disposed above the first base and extending in a second direction intersected with the first direction, the common electrode lines being configured to provide common voltage signals, wherein
the gate lines, the data lines and the common electrode lines are insulated from one another, orthographic projections of the gate lines and the data lines on the first base do not overlap, and the gate lines and/or the data lines define a plurality of sub-pixel regions together with the common electrode lines.

2. The array substrate according to claim 1, further comprising thin film transistors and pixel electrodes that are disposed above the first base, each sub-pixel region having at least one thin film transistor and a pixel electrode therein, wherein each thin film transistor includes a gate, an active pattern, a source and a drain; and
sources of all thin film transistors in each column of sub-pixel regions arranged in the first direction are electrically connected to a corresponding data line, gates of all thin film transistors in the column of sub-pixel regions are electrically connected to a respective one of the gate lines, and a drain of each thin film transistor in the column of sub-pixel regions is electrically connected to a corresponding pixel electrode.

3. The array substrate according to claim 2, wherein the pixel electrodes are disposed in a same layer and made of a same material as the common electrode lines.

4. The array substrate according to claim 1, wherein, the gate lines and the data lines are arranged alternately in the second direction; and
the gate lines and the data lines are divided into a plurality of groups each group includes a gate line and a data line most proximate to the gate line in the gate lines; and a gate line and a data line most proximate to each other in two adjacent groups define a sub-pixel region together with two adjacent common electrode lines.

5. The array substrate according to claim 1, wherein the gate lines are arranged at intervals in the second direction, and the gate lines are divided into a plurality of gate line groups, each gate line group includes two gate lines most proximate to each other in the gate lines; and
one of the data lines is disposed between the two gate lines in the gate line group; and in two adjacent gate line groups, a gate line in one gate line group most proximate to another gate line group, a gate line in the another gate line group most proximate to the one gate line group define two sub-pixel regions together with two adjacent common electrode lines.

6. The array substrate according to claim 2, wherein the gate is disposed between the active pattern and the first base as a bottom gate; and
the thin film transistor further includes a top gate disposed at a side of the source and the drain away from the first base, and the top gate is electrically connected to the bottom gate.

7. The array substrate according to claim 6, wherein a portion of a gate line connected to the thin film transistor serves as the top gate of the thin film transistor.

8. The array substrate according to claim 7, wherein, an orthographic projection of the active pattern on the first base is within a range of an orthographic projection of the bottom gate on the first base; and
the orthographic projection of the active pattern on the first base is within a range of an orthographic projection of the portion of the gate line connected to the thin film transistor on the first base.

9. The array substrate according to claim 2, wherein each thin film transistor is configured in a way that a channel of the thin film transistor is U-shaped.

10. The array substrate according to claim 2, wherein the at least one thin film transistor includes two thin film transistors.

11. The array substrate according to claim 1, further comprising common electrodes, wherein
at least one common electrode corresponds to each row of sub-pixel regions arranged in the second direction, and the at least one common electrode is electrically connected to a corresponding common electrode line.

12. The array substrate according to claim 11, wherein each common electrode is disposed in a respective one of the plurality of sub-pixel regions: or,
at least two common electrodes correspond to each row of sub-pixel regions.

13. A liquid crystal display panel, comprising the array substrate according to claim 1.

14. The liquid crystal display panel according to claim 13, further comprising:
an opposite substrate including a second base and a plurality of post spacers disposed at a side of the second base proximate to the array substrate, an orthographic projection of each post spacer on the array substrate is within a region between a gate line and a data line most proximate to each other in the gate lines and the data lines; and
a liquid crystal layer disposed between the array substrate and the opposite substrate.

15. A display device, comprising:
the liquid crystal display panel according to claim 13;
a gate driving circuit connected to the gate lines, the gate driving circuit being configured to output scanning signals to the gate lines;
a source driving circuit connected to the data lines the source driving circuit being configured to output data voltage signals to the gate lines; and
a common electrode driving circuit connected to the common electrode lines, the common electrode driving circuit being configured to output common voltage signals to the common electrode lines.

16. A method of manufacturing the array substrate according to claim 1, the method comprising:
forming the gate lines, the data lines and the common electrode lines above the first base, wherein the gate lines and the data lines extend in the first direction and the common electrode lines extend in the second direction; the gate lines, the data lines and the common electrode lines are insulated from one another; the orthographic projections of the gate lines and the data lines on the first base do not overlap; the gate lines and/or the data lines define the plurality of sub-pixel regions together with the common electrode lines.

17. The method according to claim 16, further comprising:
forming thin film transistors and pixel electrodes above the first base, wherein each sub-pixel region having at least one thin film transistor and a pixel electrode connected to the at least one thin film transistor therein, each thin film transistor includes a gate, an active pattern, a source and a drain; and
all pixel electrodes and the common electrode lines are formed by a same patterning process; the source and the drain of the thin film transistor and the data lines are formed by a same patterning process.

18. The method according to claim 17, wherein forming at least one thin film transistor and a pixel electrode in each sub pixel region, includes:
forming at least one gate on the first base by a first patterning process;
forming a gate insulating layer on the first base on which the at least one gate has been formed;
forming an active pattern corresponding to each gate on the gate insulating layer by a second patterning process;
forming a source and a drain on the active pattern by a third patterning process;
forming a first insulating layer on the source and the drain by a fourth patterning process, the first insulating layer including at least one first via hole at a position corresponding to the drain;
forming the pixel electrode on the first insulating layer by a fifth patterning process, the pixel electrode being electrically connected to the drain by the at least one first via hole;
forming a second insulating layer on the pixel electrode by a sixth patterning process, at least one second via hole extending through the second insulating layer, the first insulating layer and the gate insulating layer being formed; and
forming the gate lines on the second insulating layer by a seventh patterning process, each gate line corresponding to a respective one column of a plurality of columns of sub-pixel regions, a gate line corresponding to the sub-pixel region being electrically connected to the gate by the at least one second via hole, orthographic projections of the gate and the gate line on the first base being overlapped.

19. A method of driving the display device according to claim 15, comprising:
in an image frame:
outputting, by the gate driving circuit, scanning signals sequentially to the gate lines;
outputting, by the source driving circuit, data signals to the data lines; and
outputting, by the common electrode driving circuit, a common voltage to each of the common electrode lines.
